(19) United States
(12) Patent Application Publication
(10) Pub. No.: US 2018/0025757 A1
(43) Pub. Date: Jan. 25, 2018

(54) METHOD AND APPARATUS FOR SERIAL DATA OUTPUT IN MEMORY DEVICE

(71) Applicant: WINBOND ELECTRONICS CORPORATION, Taichung City (TW)

(72) Inventors: Johnny CHAN, Fremont, CA (US); Tinwai WONG, Fremont, CA (US)

(73) Assignee: Winbond Electronics Corporation

(21) Appl. No.: 15/213,714

(22) Filed: Jul. 19, 2016

(51) Int. Cl. G11C 7/06; G11C 7/10

(52) U.S. Cl. CPC G11C 7/062; G11C 7/10

(57) ABSTRACT

A memory device includes a memory array storing data, a sense amplifier configured to read a plurality of data bits from the memory array and output a sense data signal including the data bits read from the memory array, a data multiplexer configured to receive the sense data signal and generate a plurality of group signals, a plurality of local data registers coupled to the data multiplexer, at least one of the local data registers being configured to generate a serial data output signal according to an output mode, and a plurality of output circuits coupled to respective ones of the plurality of local data registers, at least one of the output circuits being configured to receive the serial data output signal output from the at least one of the local data registers and sequentially output the data bits included in the serial data output signal.

### FIELD OF THE DISCLOSURE

The present disclosure relates to a method and apparatus for serial data output in a memory device.

### BACKGROUND

Serial flash memory devices have become popular due to low pin count and simple input/output interface. The serial flash memory devices employ a single-bit Serial Peripheral Interface (“SPI”) protocol, or a multiple-bit SPI protocol. The single-bit SPI protocol involves serially outputting data via a single input/output (IO) pin. The multiple-bit SPI protocol can include a Dual SPI protocol, a Quad SPI protocol, and a Quad Peripheral Interface (“QPI”) protocol. The Dual SPI protocol involves serially outputting data via two IO pins. The Quad SPI protocol and the QPI protocol involve serially outputting data via four IO pins. Memory devices employing the multiple-bit SPI protocol can be used for high performance system applications which require fast read performance.

### SUMMARY

According to an embodiment of the disclosure, a memory device includes a memory array storing data, a sense amplifier coupled to the memory array and configured to read a plurality of data bits from the memory array and output a sense data signal including the data bits read from the memory array: a data multiplexer coupled to the sense amplifier and configured to receive the sense data signal to generate a sense amplifier signal, and select a plurality of groups of data bits from the sense amplifier signal according to a bit map to generate a plurality of group signals respectively including the plurality of groups of data bits; a plurality of local data registers coupled to the data multiplexer to receive respective ones of the plurality of group signals, at least one of the local data registers being configured to generate a serial data output signal including at least a subset of the data bits included in one of the group signals corresponding to the at least one of the local data registers according to an output mode; and a plurality of output circuits coupled to respective ones of the plurality of local data registers, at least one of the output circuits being configured to receive the serial data output signal output from the at least one of the local data registers and sequentially output the data bits included in the serial data output signal.

According to another embodiment of the disclosure, a method for reading data from a memory device is provided. The memory device includes a memory array, a sense amplifier coupled to the memory array, a data multiplexer coupled to the sense amplifier, a plurality of local data registers coupled to the data multiplexer, and a plurality of output circuits respectively coupled to the plurality of local data registers. The method includes reading, by the sense amplifier, a plurality of data bits from the memory array to generate a sense data signal including the plurality of data bits read from the memory array; generating, by the data multiplexer, a sense amplifier signal from the sense data signal; selecting, by the data multiplexer, a plurality of groups of data bits from the sense amplifier signal to generate a plurality of group signals; receiving, by the plurality of local data registers, respective ones of the plurality of group signals generated by the data multiplexer; generating, by at least one of the local data registers, a serial data output signal including at least a subset of the data bits included in one of the group signals corresponding to the at least one of the local data registers according to an output mode, and outputting the serial data output signal to at least one of the output circuits; and sequentially outputting, by the at least one of the output circuits, the data bits included in the serial data output signals.

The accompanying drawings, which are incorporated in and constitute a part of this application, illustrate disclosed embodiments and, together with the description, serve to explain the disclosed embodiments.

### BRIEF DESCRIPTION OF THE DRAWINGS

FIG. 1 is a diagram of a semiconductor chip formed with a memory device, according to a comparative example.

FIG. 2 schematically illustrates data bits included in various signals for different output modes, according to a comparative example.

FIG. 3 is a timing diagram for a read operation in the memory device of FIG. 1, according to a comparative example.

FIG. 4 is a schematic diagram of a semiconductor chip formed with a memory device, according to an illustrated embodiment.

FIG. 5 schematically illustrates data bits included in various signals for different output modes, according to an illustrated embodiment.

FIG. 6 is a timing diagram for a read operation in the memory device of FIG. 4, according to an illustrated embodiment.

### DETAILED DESCRIPTION

Reference will now be made in detail to the present embodiments, examples of which are illustrated in the accompanying drawings. Wherever possible, the same reference numbers will be used throughout the drawings to refer to the same or like parts.

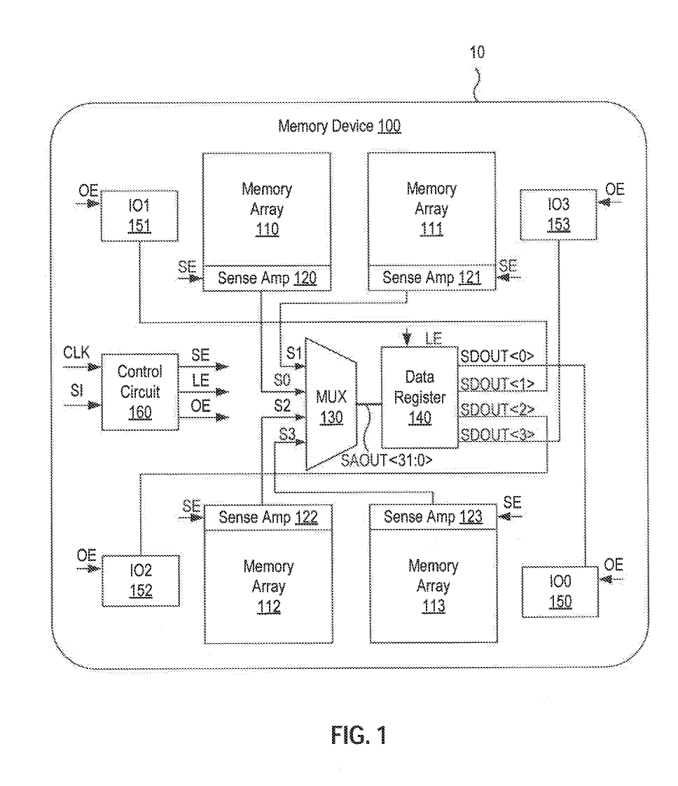

FIG. 1 is a schematic diagram of a semiconductor chip 10 formed to include a memory device 100, according to a comparative example. Memory device 100 includes first to fourth memory arrays 110-113, first to fourth sense amplifiers 120-123, a data multiplexer 130, a data register 140, first to fourth input/output circuits 150-153, and a control circuit 160.

First to fourth memory arrays 110-113 are separated from each other. Each one of first to fourth memory arrays 110-113 includes a plurality of memory cells (not shown) for storing data.

First to fourth sense amplifiers 120-123 (each denoted “Sense Amp” in FIG. 1) are respectively coupled to first to fourth memory arrays 110-113, and are controlled by a sense enable signal SE generated by control circuit 160. First to fourth sense amplifiers 120-123 are configured to read data bits from first to fourth memory arrays 110-113, respectively, to generate first to fourth sense data signals S0-S3 and output the first to fourth sense data signals S0-S3 to data multiplexer 130. First to fourth sense data signals S0-S3 include the data bits read from first to fourth memory arrays 110-113, respectively. For example, first sense amplifier 120 reads a plurality of data bits from first memory array 110 and outputs first sense data signal S0 to data multiplexer 130, second sense amplifier 121 reads a plurality of data bits from second memory array 111 and outputs sense data signal S1 to data multiplexer 130, and so on.

Data multiplexer 130 (denoted “MUX 130” in FIG. 1) is disposed at a central region of semiconductor chip 10 and is coupled to first to fourth sense amplifiers 120-123 to receive sense data signals S0-S3 respectively outputted from first to fourth sense amplifiers 120-123. Data multiplexer 130 is configured to combine sense data signals S0-S3 to generate a sense amplifier signal SAOUT including all of the data bits in sense data signals S0-S3. In the example illustrated in FIG. 1, the number of the data bits in all of sense data signals S0-S3 is thirty-two (32), and thus sense amplifier signal SAOUT includes thirty-two data bits and is denoted “SAOUT<31:0>” in FIG. 1.

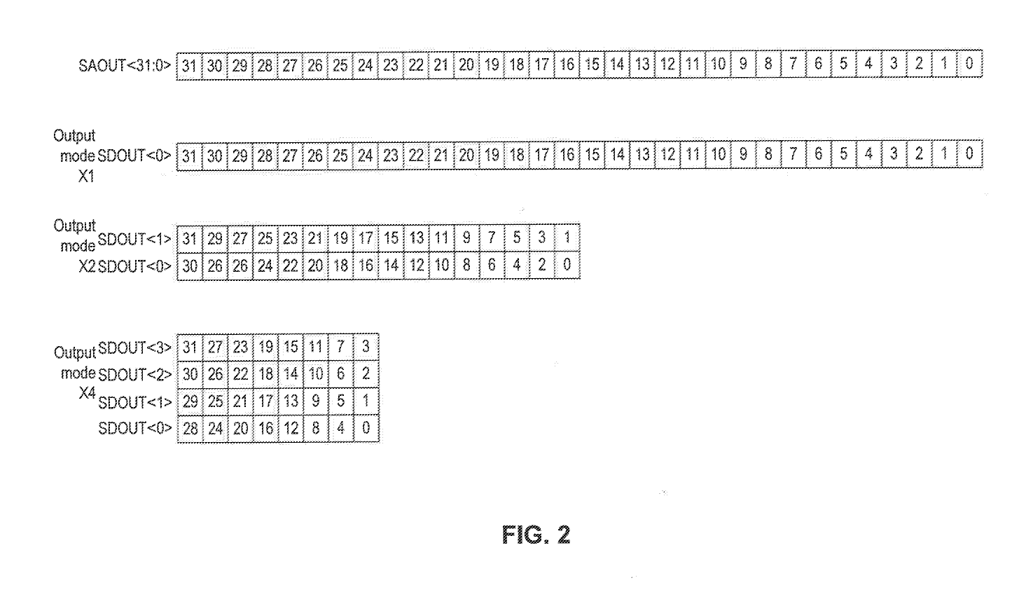

Data register 140 is disposed at the central region of semiconductor chip 10 close to data multiplexer 130 and is coupled to data multiplexer 130 to receive sense amplifier signal SAOUT<31:0> from data multiplexer 130. Data register 140 is controlled by a latch enable signal LE generated by control circuit 160. Data register 140 is configured to store the data bits included in sense amplifier signal SAOUT<31:0> and, in accordance with an output mode, select at least one of first to fourth groups of data bits included in sense amplifier signal SAOUT<31:0> to generate at least one of first to fourth serial data output signals SDOUT<0>-SDOUT<3>, and output the at least one of first to fourth serial data output signals SDOUT<0>-SDOUT<3> to at least one of first to fourth input/output circuits 150-153. The output mode can be one of a single-bit serial mode corresponding to the single-bit SPI protocol, a two-bit serial mode corresponding to the Dual SPI protocol, and a four-bit serial mode corresponding to the Quad SPI protocol or the QPI protocol. The output mode can be selected by a user, and input to memory device 100. First to fourth serial data output signals SDOUT<0>-SDOUT<3> will be described in more detail with reference to FIG. 2.

First to fourth input/output circuits 150-153 (denoted “IO0”-“IO3” in FIG. 1) are disposed at a peripheral region of semiconductor chip 10 and are coupled to data register 140 to receive respective ones of the first to fourth serial data output signals SDOUT<0>-SDOUT<3>. First to fourth input/output circuits 150-153 are controlled by an output enable signal OE generated by control circuit 160. Each one of first to fourth input/output circuits 150-153 includes an IO pin (not shown) and is configured to sequentially output the data bits included in the corresponding one of the first to fourth serial data output signals SDOUT<0>-SDOUT<3> via the IO pin, with one bit at a time, e.g., one bit per clock cycle.

Control circuit 160 is coupled to receive a serial input signal SI and a clock signal CLK, and is configured to generate a plurality of control signals responsive to the serial input signal SI and the clock signal CLK to control operations of various components of memory device 100, such as first to fourth memory arrays 110-113, first to fourth sense amplifiers 120-123, data multiplexer 130, data register 140, and first to fourth input/output circuits 150-153. In the example of FIG. 1, the serial input signal SI includes a read command and an address of one of first to fourth memory arrays 110-113 from which data should be read. In response to the serial input signal SI, control circuit 160 generates and outputs the sense enable signal SE, the latch enable signal LE, and output enable signal OE to first to fourth sense amplifiers 120-123, data register 140, and first to fourth input/output circuits 150-153, respectively.

FIG. 2 schematically illustrates data bits included in sense amplifier signal SAOUT<31:0>, and first to fourth serial data output signals SDOUT<0>-SDOUT<3> for different output modes, according to a comparative example. In the example illustrated in FIG. 2, sense amplifier signal SAOUT<31:0> generated by data multiplexer 130 includes thirty-two (32) data bits, i.e., bit 0, bit 1, . . . , bit 31.

When the output mode is the single-bit serial mode (denoted “Output mode X1” in FIG. 2), data register 140 selects all of the thirty-two data bits included in sense amplifier signal SAOUT<31:0> to generate first output signal SDOUT<0> consisting of the thirty-two data bits, and outputs first output signal SDOUT<0> to first input/output circuit 150. Then, first input/output circuit 150 sequentially outputs the thirty-two data bits included in SDOUT<0>, with one bit per clock cycle starting from bit 0.

When the output mode is the two-bit serial mode (denoted “Output mode X2” in FIG. 2), data register 140 selects a first group of sixteen (16) data bits including bit 0, bit 2, . . . , bit 30 included in sense amplifier signal SAOUT<31:0>, generates first output signal SDOUT<0> consisting of the first group of data bits, and outputs first output signal SDOUT<0> to first input/output circuit 150. In addition, data register 140 selects a second group of sixteen data bits including bit 1, bit 3, . . . , bit 31 included in sense amplifier signal SAOUT<31:0>, generates second output signal SDOUT<1> consisting of the second group of data bits, and outputs second output signal SDOUT<1> to second input/output circuit 151. Then, first input/output circuit 150 and second input/output circuit 151 concurrently and sequentially output two data bits included in respective ones of first output signal SDOUT<0> and second output signal SDOUT<1>, with each one of first input/output circuit 150 and second input/output circuit 151 outputting one data bit per clock cycle. For example, at a first clock cycle, first input/output circuit 150 outputs bit 0 and second input/output circuit 151 outputs bit 1; at a second clock cycle immediately following the first clock cycle, first input/output circuit 150 outputs bit 2 and second input/output circuit 151 outputs bit 3; at a third clock cycle immediately following the second clock cycle, first input/output circuit 150 outputs bit 4 and second input/output circuit 151 outputs bit 5; and so on.

When the output mode is the four-bit serial mode (denoted “Output mode X4” in FIG. 2), data register 140 selects a first group of eight (8) data bits including bit 0, bit 4, . . . , bit 28 included in sense amplifier signal SAOUT<31:0>, generates first output signal SDOUT<0> consisting of the first group of data bits, and outputs first output signal SDOUT<0> to first input/output circuit 150. In addition, data register 140 selects a second group of eight data bits including bit 1, bit 5, . . . , bit 29 included in sense amplifier signal SAOUT<31:0>, generates second output signal SDOUT<1> consisting of the second group of data bits, and outputs second output signal SDOUT<1> to second input/output circuit 151. Data register 140 also selects a third group of eight data bits including bit 2, bit 6, . . . , bit 30 included in sense amplifier signal SAOUT<31:0>, generates third output signal SDOUT<2> consisting of the third group of data bits, and outputs third output signal SDOUT<2> to third input/output circuit 152. Data register 140 further selects a fourth group of eight data bits including bit 3, bit 7, . . . , bit 31 included in sense amplifier signal SAOUT<31:0>, generates fourth output signal SDOUT<3> consisting of the fourth group of data bit and outputs fourth output signal SDOUT<3> to fourth input/output circuit 153. Then, first to fourth input/output circuits 150-153 concurrently and sequentially output four data bits included in respective ones of first to fourth output signals SDOUT<0>-SDOUT<3>, with each one of first to fourth input/output circuits 150-153 outputting one data bit per clock cycle. For example, at a first clock cycle, first to fourth input/output circuits 150-153 output bit 0, bit 1, bit 2, and bit 3, respectively; at a second clock cycle immediately following the first clock cycle, first to fourth input/output circuits 150-153 output bit 4, bit 5, bit 6, and bit 7, respectively; at a third clock cycle immediately following the second clock cycle, first to fourth input/output circuits 150-153 output bit 8, bit 9, bit 10, and bit 11, respectively; and so on.

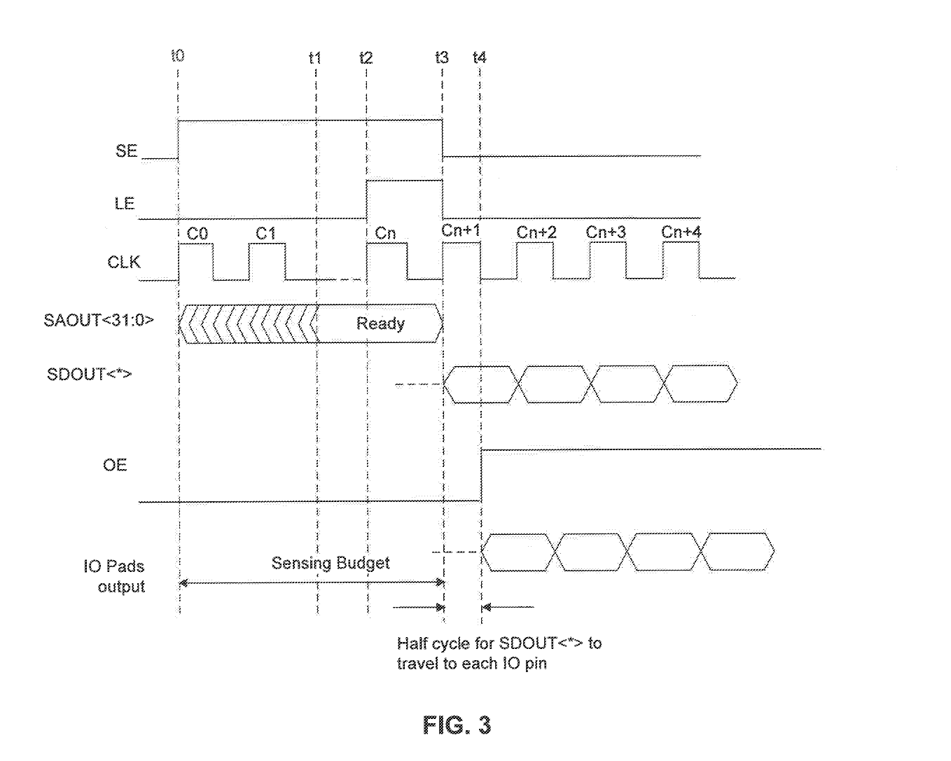

FIG. 3 is a timing diagram for a read operation in memory device 100, according to a comparative example.

Referring to FIGS. 1 and 3, at time t0, which is the rising edge of clock cycle C0, sense enable signal SE transitions from a low level to a high level, which enables first to fourth sense amplifiers 120-123 to read data bits from the respective ones of first to fourth memory arrays 110-113 to generate first to fourth sense data signals S0-S3, and output the respective ones of first to fourth sense data signals S0-S3 to data multiplexer 130. Data multiplexer 130 combines first to fourth sense data signals S0-S3 to generate sense amplifier signal SAOUT<31:0>.

At time t1, which is a time point between the rising edge of clock cycle C0 and the rising edge of clock cycle Cn (n being an integer greater than 1), first to fourth sense amplifiers 120-123 finish reading the data bits from the respective ones of first to fourth memory arrays 110-113, and data multiplexer 130 finishes combining first to fourth sense data signals S0-S3 to generate sense amplifier signal SAOUT<31:0>. Thus sense amplifier signal SAOUT<31:0> is ready to be stored (i.e., latched) by data register 140.

At time t2, which is the rising edge of clock cycle Cn, the latch enable signal LE transitions from a low level to a high level, which enables data register 140 to store (i.e., latch) the data bits included in sense amplifier signal SAOUT<31:0>.

At time t3, which is the rising edge of clock cycle Cn+1, the sense enable signal SE transitions from the high level to the low level. As a result, first to fourth sense amplifiers 120-123 stop reading the data bits from first to fourth memory arrays 110-113. In the meantime, the latch enable signal LE transitions from the high level to the low level, which enables data register 140 to generate at least one of first to fourth serial data output signals SDOUT<0>-SDOUT<3> (collectively denoted “SDOUT<*>” in FIG. 3) and to output the at least one of first to fourth serial data output signals SDOUT<0>-SDOUT<3> to at least one of first to fourth input/output circuits 150-153.

At time t4, which is the failing edge of clock cycle Cn+1, output enable signal OE transitions from a low level to a high level, which enables the at least one of first to fourth input/output circuits 150-153 to sequentially output the data bits included in the at least one of first to fourth serial data output signals SDOUT<0>-SDOUT<3> via a corresponding one of the IO pins.

According to the timing diagram of FIG. 3, during the time period from time t3 to time t4 which is one-half clock cycle, first to fourth serial data output signals SDOUT<0>-SDOUT<3> travel from data register 140 to the respective ones of first to fourth input/output circuits 150-153. However, as the frequency of clock signal CLK increases, the time period provided by the one-half clock cycle decreases. As a result, the time available for first to fourth serial data output signals SDOUT<0>-SDOUT<3> to travel to the respective ones of first to fourth input/output circuits 150-153 decreases.

In addition, as the density of memory cells in memory device 100 increases, the distance between data register 140 and each one of first to fourth input/output circuits 150-153 increases. As a result, the distance for first to fourth serial data output signals SDOUT<0>-SDOUT<3> to travel from data register 140 to respective ones of first to fourth input/output circuits 150-153, increases.

In a worst case scenario, when the frequency of clock signal CLK increases beyond a certain level, and/or the density of memory device 100 increases beyond a certain level, the one-half clock cycle from time t3 to time t4 may become insufficient for first to fourth serial data output signals SDOUT<0>-SDOUT<3> to travel from data register 140 to the respective ones of first to fourth input/output circuits 150-153. Thus, the one-half clock cycle may represent a bottleneck for the reading operation of memory device 100.

In order to eliminate the bottleneck presented by the one-half clock cycle for first to fourth serial data output signals SDOUT<0>-SDOUT<3> to travel from data register 140 to the respective ones of first to fourth input/output circuits 150-153, according to embodiments of the present disclosure, data register 140 is partitioned into four local data registers respectively corresponding to and disposed close to first to fourth input/output circuits 150-153. As a result, first to fourth serial data output signals SDOUT<0>-SDOUT<3> can be transmitted locally from the respective ones of the local data registers to the respectively ones of first to fourth input/output circuits 150-153 during the one-half clock cycle from t3 to t4.

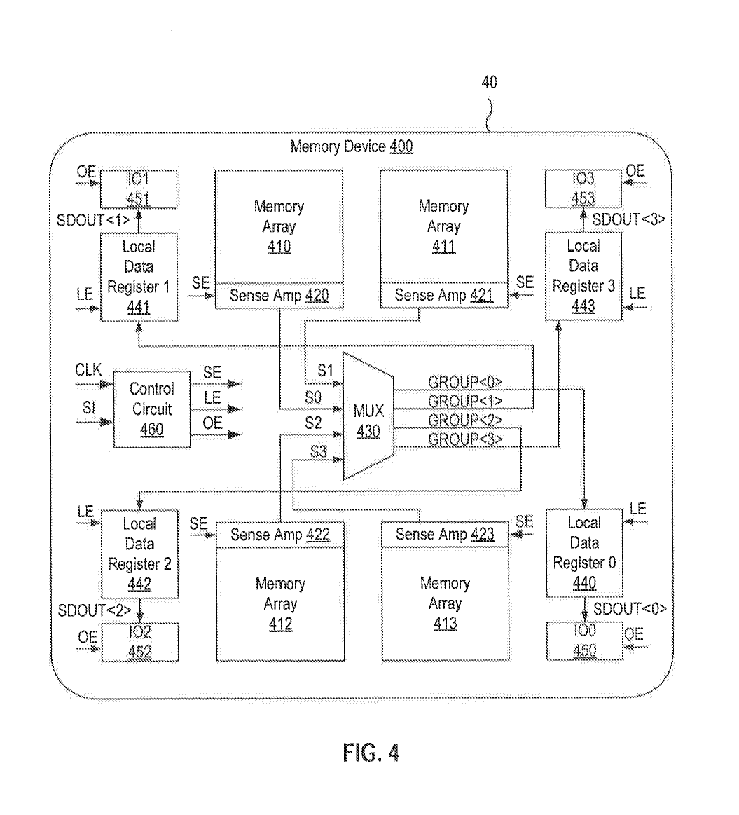

FIG. 4 is a schematic diagram of a semiconductor chip 40 formed to include a memory device 400, according to an embodiment described above. Memory device 400 includes first to fourth memory arrays 410-413, first to fourth sense amplifiers 420-423, a data multiplexer 430, first to fourth local data registers 440-443, first to fourth input/output circuits 450-453, and a control circuit 460.

First to fourth memory arrays 410-413 are separated from each other. Each one of first to fourth memory arrays 410-413 includes a plurality of memory cells (not shown) for storing data.

First to fourth sense amplifiers 420-423 (each denoted “Sense Amp” in FIG. 4) are respectively coupled to first to fourth memory arrays 410-413, and are controlled by a sense enable signal SE generated by control circuit 460. First to fourth sense amplifiers 420-423 are configured to read data bits from first to fourth memory arrays 410-413, respectively, to generate first to fourth sense data signals S0-S3 and output the first to fourth sense data signals S0-S3 to data multiplexer 430. First to fourth sense data signals S0-S3 include the data bits read from first to fourth memory arrays 410-413, respectively. For example, first sense amplifier 420 reads a plurality of data bits from first memory array 410 and outputs first sense data signal S0 to data multiplexer 430, second sense amplifier 421 reads a plurality of data bits from second memory array 411 and outputs second sense data signal S1 to data multiplexer 430, and so on.

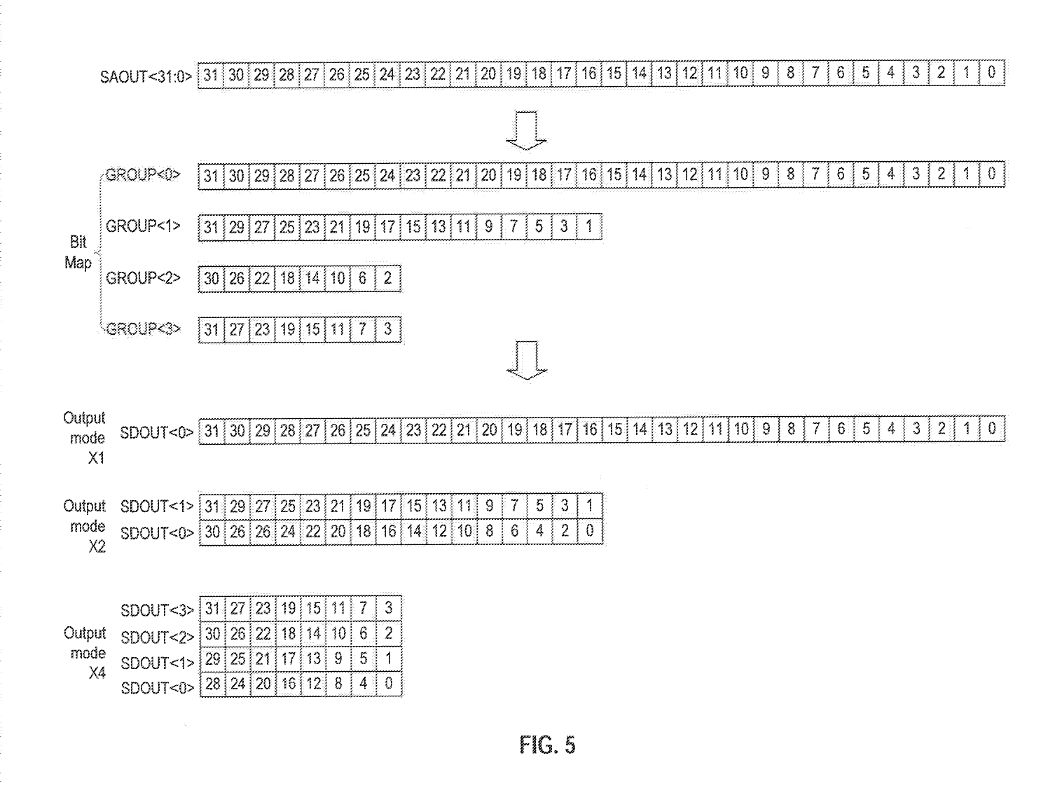

Data multiplexer 430 (denoted “MUX 430” in FIG. 4) is disposed at a central region of semiconductor chip 40 and is coupled to first to fourth sense amplifiers 420-423 to receive sense data signals S0-S3 respectively outputted from first to fourth sense amplifiers 420-423. Data multiplexer 430 is configured to combine sense data signals S0-S3 to generate a sense amplifier signal SAOUT including all of the data bits in sense data signals S0-S3. In the embodiment illustrated in FIG. 4, sense amplifier signal SAOUT includes thirty-two data bits and will be referred to as SAOUT<31:0>. Data multiplexer 430 is also configured to select first to fourth groups of data bits included in sense amplifier signal SAOUT<31:0> according to a bit map to generate first to fourth group signals GROUP<0>-GROUP<3> respectively including the first to fourth groups of data bits, and output first to fourth group signals GROUP<0>-GROUP<3> to respective ones of first to fourth local data registers 440-443. The bit map and first to fourth group signals GROUP<0>-GROUP<3> will be described in more detail with reference to FIG. 5. For example, data multiplexer 430 can include first to fourth data multiplexers. Each one of first to fourth data multiplexers receives all of sense data signals S0-S3 generates a corresponding one of first to fourth group signals GROUP<0>-GROUP<3> based on the bit map, and transmits the generated group signal to a corresponding one of first to fourth local data registers 440-443.

First to fourth local data registers 440-443 are disposed at a peripheral region of semiconductor chip 40 and are coupled to data multiplexer 430 to receive first to fourth group signals GROUP<0>-GROUP<3>, respectively. In the embodiment illustrated in FIG. 4, first to fourth local data registers 440-443 are disposed in the peripheral region near respective ones of four corners of semiconductor chip 40. First to fourth local data registers 440-443 are controlled by a latch enable signal LE generated by control circuit 460 to store the data bits included in first to fourth group signals GROUP<0>-GROUP<3>, respectively, and, in accordance with an output mode, select at least one of first to fourth subsets of the data bits included in first to fourth group signals GROUP<0>-GROUP<3> to generate at least one of first to fourth serial data output signals SDOUT<0>-SDOUT<3>, and output the at least one of first to fourth serial data output signals SDOUT<0>-SDOUT<3> to first to fourth input/output circuits 450-453, respectively. For example, each one of first to fourth local data registers 440-443 includes a data multiplexer for selecting the data bits and generating the corresponding one of the first to fourth serial data output signals SDOUT<0>-SDOUT<3>. The output mode can be one of a single-bit serial mode, a two-bit serial mode, and a four-bit serial mode. The output mode can be selected by a user, or an external device. First to fourth serial data output signals SDOUT<0>-SDOUT<3> will be described in more detail with reference to FIG. 5.

First to fourth input/output circuits 450-453 (denoted “IO0”-“IO3” in FIG. 4) are disposed in the peripheral region of semiconductor chip 40 near respective corners and close to first to fourth local data registers 440-443 to receive first to fourth serial data output signals SDOUT<0>-SDOUT<3>, respectively. A distance between each one of first to fourth input/output circuits 450-453 and the corresponding one of first to fourth local data registers 440-443 is less than a distance between the corresponding one of first to fourth local data registers 440-443 and data multiplexer 430. First to fourth input/output circuits 450-453 are controlled by an output enable signal OE generated by control circuit 460. Each one of first to fourth input/output circuits 450-453 includes an IO pin (not shown) and is configured to sequentially output the data bits included in the corresponding one of the first to fourth serial data output signals SDOUT<0>-SDOUT<3> via the IO pin, with one bit at a time, e.g., one bit per clock cycle.

Control circuit 460 is coupled to receive a serial input signal SI and the clock signal CLK, and is configured to generate a plurality of control signals responsive to the serial input signal SI and the clock signal CLK to control operations of various components of memory device 400, such as first to fourth memory arrays 410-413, first to fourth sense amplifiers 420-423, data multiplexer 430, first to fourth local data registers 440-443, and first to fourth input/output circuits 450-453. In the embodiment of FIG. 4, the serial input signal SI includes a read command and an address of one of first to fourth memory arrays 410-413 from which data should be read. In response to the serial input signal SI, control circuit 460 generates and outputs the sense enable signal SE, the latch enable signal LE, and output enable signal OE to first to fourth sense amplifiers 420-423, first to fourth local data registers 440-443, and first to fourth input/output circuits 450-453, respectively.

FIG. 5 schematically illustrates data bits included in sense amplifier signal SAOUT<31:0>, first to fourth group signals GROUP<0>-GROUP<3>, and serial data output signals SDOUT<0>-SDOUT<3> for different output modes, according to an illustrated embodiment. In the example illustrated in FIG. 5, sense amplifier signal SAOUT<31:0> generated by data multiplexer 130 includes thirty-two (32) data bits, i.e., bit 0, bit 1, . . . , bit 31.

According to FIG. 5, data multiplexer 430 receives sense amplifier signal SAOUT<31:0>, selects a first group of data bits consisting of all of the thirty-two data bits included in sense amplifier signal SAOUT<31:0>, generates first group signal GROUP<0> consisting of the first group of thirty-two data bits, and outputs first group signal GROUP<0> to first local data register 440. In addition, data multiplexer 430 selects a second group of sixteen (16) data bits including bit 1, bit 3, . . . , bit 31 included in sense amplifier signal SAOUT<31:0>, generates second group signal GROUP<1> consisting of the second group of data bits, and outputs second group signal GROUP<1> to second local data register 441. Data multiplexer 430 also selects a third group of eight (8) data bits including bit 2, bit 6, . . . , bit 30 included in sense amplifier signal SAOUT<31:0>, generates third group signal GROUP<2> consisting of the third group of data bits, and outputs third group signal GROUP<2> to third local data register 442. Data multiplexer 430 further selects a fourth group of eight (8) data bits including bit 3, bit 7, . . . , bit 31 included in sense amplifier signal SAOUT<31:0>, generates fourth group signal GROUP<3> consisting of the fourth group of data bits, and outputs fourth group signal GROUP<3> to fourth local data register 443.

When the output mode is the single-bit serial mode (denoted “Output mode X1” in FIG. 5), local data register 440 selects all of the thirty-two data bits included in first group signal GROUP<0> to generate first output signal SDOUT<0> consisting of the thirty-two data bits, and outputs first output signal SDOUT<0> to first input/output circuit 450. Then, first input/output circuit 450 sequentially output the thirty-two data bits included in SDOUT<0>, with one bit per clock cycle starting from bit 0.

When the output mode is the two-bit serial mode (denoted “Output mode X2” in FIG. 5), first local data register 440 selects a subset of sixteen (16) data bits including bit 0, bit 2, . . . , bit 30 included in first group signal GROUP<0>, generates first output signal SDOUT<0> consisting of the selected subset of data bits, and outputs first output signal SDOUT<0> to first input/output circuit 450. In addition, second local data register 441 selects all of the sixteen data bits including bit 1, bit 3, . . . , bit 31 included in second group signal GROUP<1>, generates second output signal SDOUT<1> consisting of the selected data bits, and outputs second output signal SDOUT<1> to second input/output circuit 451. Then, first input/output circuit 450 and second input/output circuit 451 concurrently and sequentially output two data bits included in respective ones of first output signal SDOUT<0> and second output signal SDOUT<1>, with each one of first input/output circuit 450 and second input/output circuit 451 outputting one data bit per clock cycle. For example, at a first clock cycle, first input/output circuit 450 outputs bit 0 and second input/output circuit 451 outputs bit 1; at a second clock cycle immediately following the first clock cycle, first input/output circuit 450 outputs bit 2 and second input/output circuit 451 outputs bit 3; at a third clock cycle immediately following the second clock cycle, first input/output circuit 450 outputs bit 4 and second input/output circuit 451 outputs bit 5; and so on.

When the output mode is the four-bit serial mode (denoted “Output mode X4” in FIG. 5), first local data register 440 selects a subset of eight (8) data bits including bit 0, bit 4, . . . , bit 28 included in first group signal GROUP<0>, generates first output signal SDOUT<0> consisting of the selected subset of data bits, and outputs first output signal SDOUT<0> to first input/output circuit 450. In addition, second local data register 441 selects a subset of eight data bits including bit 1, bit 5, . . . , bit 29 included in in second group signal GROUP<1>, generates second output signal SDOUT<1> consisting of the selected subset of data bits, and outputs second output signal SDOUT<1> to second input/output circuit 451. Third local data register 442 selects all of the eight data bits including bit 2, bit 6, . . . , bit 30 included in third group signal GROUP<2>, generates third output signal SDOUT<2> consisting of the selected data bits, and outputs third output signal SDOUT<2> to third input/output circuit 452. Fourth local data register 443 selects all of the eight data bits including bit 3, bit 7, . . . , bit 31 included in fourth group signal GROUP<3>, generates fourth output signal SDOUT<3> consisting of the selected data bits, and outputs the fourth output signal SDOUT<3> to fourth input/output circuit 453. Then, first to fourth input/output circuits 450-453 concurrently and sequentially output four data bits included in respective ones of first to fourth output signals SDOUT<0>-SDOUT<3>, with each one of first to fourth input/output circuits 450-453 outputting one data bit per clock cycle. For example, at a first clock cycle, first to fourth input/output circuits 450-453 output bit 0, bit 1, bit 2, and bit 3, respectively; at a second clock cycle immediately following the first clock cycle, first to fourth input/output circuits 450-453 output bit 4, bit 5, bit 6, and bit 7, respectively; at a third clock cycle immediately following the second clock cycle, first to fourth input/output circuits 450-453 output bit 8, bit 9, bit 10, and bit 11, respectively; and so on.

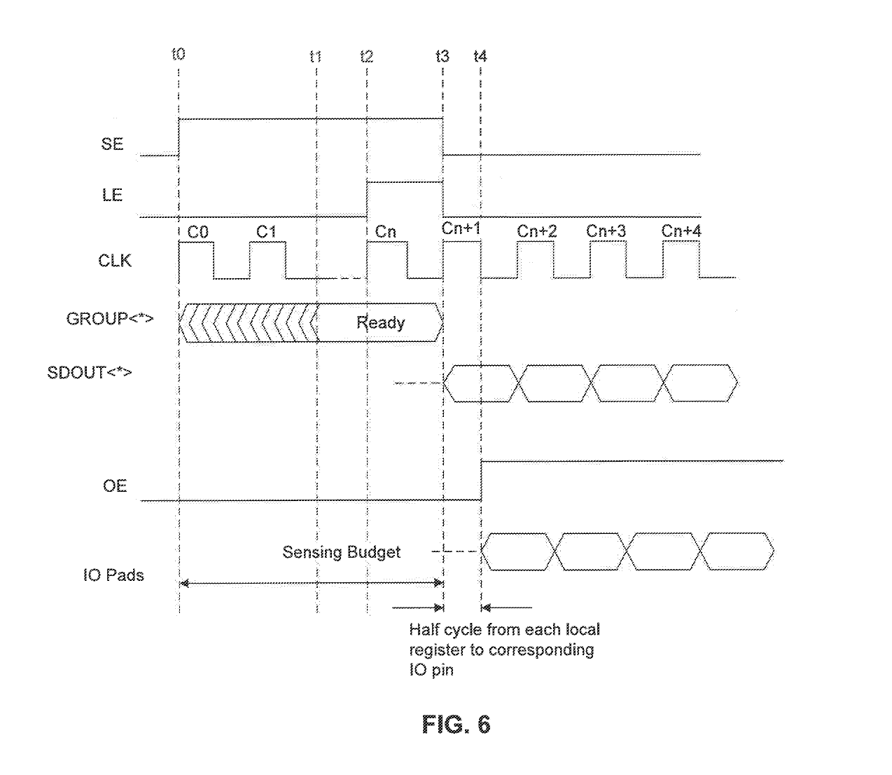

FIG. 6 is a timing diagram for a read operation in memory device 400, according to the illustrated embodiment.

Referring to FIGS. 4 and 6, at time t0, which is the rising edge of clock cycle C0, sense enable signal SE transitions from a low level to a high level, which enables first to fourth sense amplifiers 420-423 to read data bits from first to fourth memory arrays 410-413, respectively, to generate first to fourth sense data signals S0-S3, and output respective ones of first to fourth sense data signals S0-S3 to data multiplexer 430. Data multiplexer 430 combines the first to fourth sense data signals S0-S3 to generate sense amplifier signal SAOUT<31:0>, generates first to fourth group signals GROUP<0>-GROUP<3> from sense amplifier signal SAOUT<31:0>, and outputs first to fourth group signals GROUP<0>-GROUP<3> to first to fourth local data registers 440-443, respectively. Then, first to fourth group signals GROUP<0>-GROUP<3> are distributed from data multiplexer 430 to first to fourth local data registers 440-443, respectively. In some embodiments, each one of first to fourth group signals GROUP<0>-GROUP<3> can be transmitted in parallel.

At time t1, which is a time point between the rising edge of clock cycle C0 and the rising edge of clock cycle Cn (n being an integer greater than 1), first to fourth group signals GROUP<0>-GROUP<3> are received at first to fourth local data registers 440-443, and thus first to fourth group signals GROUP<0>-GROUP<3> are ready to be stored (i.e., latched) by first to fourth local data registers 440-443, respectively.

At time t2, which is the rising edge of clock cycle Cn+1, the latch enable signal LE transitions from a low level to a high level, which enables first to fourth local data registers 440-443 to store (i.e., latch) the data bits included in first to fourth group signals GROUP<0>-GROUP<3>, respectively.

At time t3, which is the rising edge of a clock cycle Cn+1 following clock cycle Cn, the sense enable signal SE transitions from the high level to the low level. In response, first to fourth sense amplifiers 420-423 stop reading the data bits from first to fourth memory arrays 410-413. In the meantime, the latch enable signal LE transitions from the high level to the low level, which enables at least one of first to fourth local data registers 440-443 to generate at least one of first to fourth serial data output signals SDOUT<0>-SDOUT<3> (collectively denoted “SDOUT<*>” in FIG. 1), and output the at least one of first to fourth serial data output signals SDOUT<0>-SDOUT<3> to at least one of first to fourth input/output circuits 450-453.

At time t4, which is the falling edge of clock cycle Cn+1, output enable signal OE transitions from a low level to a high level, which enables the at least one of first to fourth input/output circuits 450-453 to sequentially output the data bits included in the at least one of first to fourth serial data output signals SDOUT<0>-SDOUT<3> via one of the IO pins.

According to the timing diagram of FIG. 6, during the time period from time t3 to time t4, which is one-half clock cycle, first to fourth serial data output signals SDOUT<0>-SDOUT<3> travel from first to fourth local data registers 440-443 to first to fourth input/output circuits 450-453, respectively. As previously described, first to fourth input/output circuits 450-453 are disposed close to first to fourth local data registers 440-443, respectively. Therefore, the distance from first to fourth local data registers 440-443 to first to fourth input/output circuits 450-453, respectively, is relatively short, compared to the comparative example of FIG. 1 in which the distance from data register 140 to each one of first to fourth input/output circuits 150-153 is relatively long. As a result, it takes relatively less time for first to fourth serial data output signals SDOUT<0>-SDOUT<3> to propagate from first to fourth local data registers 440-443 to first to fourth input/output circuits 450-453, respectively. Consequently, the one-half clock cycle can be sufficient for first to fourth serial data output signals SDOUT<0>-SDOUT<3> to travel from first to fourth local data registers 440-443 to first to fourth input/output circuits 450-453, respectively. Thus, the one-half clock cycle does not present a bottleneck for the reading operation of memory device 400.

In addition, according to the timing diagram of FIG. 6, first to fourth group signals GROUP<0>-GROUP<3> propagate from data multiplexer 430 to local data registers 440-443, respectively, during the time period from t0 to t3, which is within a sensing budget. Generally, the sensing budget is configured to be relative long in order to ensure that data can be read from first to fourth memory arrays 410-413. Therefore, propagation of first to fourth group signals GROUP<0>-GROUP<3> from data multiplexer 430 to local data registers 440-443 does not affect the sensing budget.

In the embodiment described with reference to FIGS. 4-6, memory device 400 including four input/output circuits 450-453 has been described as an example. It will now be apparent to those skilled in the art that the memory device can include more or less than four input/output circuits, for example, eight (8) or sixteen (16) input/output circuits. In such case, the number of the group signals output by the data multiplexer and the number of local data registers are equal to the number of input/output circuits. For example, if a memory device includes eight input/output circuits, the memory device would include eight local data registers respectively coupled to the eight input/output circuits, and a data multiplexer of the memory device would output eight group signals to respective ones of the eight local data registers. As another example, if a memory device includes sixteen input/output circuits, the memory device would include sixteen local data registers respectively coupled to the sixteen input/output circuits, and a data multiplexer of the memory device would output sixteen group signals to respective ones of the eight local data registers.

In the embodiment described with reference to FIGS. 4-6, memory device 400 including four memory arrays 410-413 has been described as an example. It will now be apparent to those skilled in the art that the memory device can include more or less than four memory arrays, for example, a single memory array, two memory arrays, or eight memory arrays. In the case of a memory device including a single memory array, the memory device includes a single sense amplifier to sense data from the single memory array. In the case of a memory device including two memory arrays, the memory device includes two sense amplifiers to sense data from the two memory arrays. That is, the number of sense amplifiers is equal to the number of memory arrays.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A memory device, comprising:
a memory array storing data;
a sense amplifier coupled to the memory array and configured to read a plurality of data bits from the memory array and output a sense data signal including the data bits read from the memory array;
a data multiplexer coupled to the sense amplifier and configured to receive the sense data signal to generate a sense amplifier signal, and select a plurality of groups of data bits from the sense amplifier signal according to a bit map to generate a plurality of group signals respectively including the plurality of groups of data bits;
a plurality of local data registers independent of each other and coupled to the data multiplexer to receive respective ones of the plurality of group signals, each one of the local data registers being configured to generate a serial data output signal including at least a subset of the data bits included in a corresponding one of the group signals according to an output mode; and
a plurality of output circuits independent of each other and coupled to respective ones of the plurality of local data registers, each one of the output circuits being configured to receive the serial data output signal output from a corresponding one of the local data registers and sequentially output the data bits included in the serial data output signal.

2. The memory device of claim 1, wherein the memory device is formed on a semiconductor chip,
the plurality of output circuits being disposed at a peripheral region of the semiconductor chip,
a distance between each one of the plurality of local data registers and the data multiplexer being greater than a distance between the local data register and its corresponding output circuit coupled to the local data register.

3. The memory device of claim 1, wherein the memory device includes four of the local data registers and four of the output circuits,
the output mode being one of a single-bit serial mode, a two-bit serial mode, and a four-bit serial mode.

4. The memory device of claim 3, wherein the data multiplexer is configured to:
generate a first group signal including all of the data bits included in the sense amplifier signal and output the first group signal to a first one of the local data registers;
generate a second group signal including one-half of the data bits included in the sense amplifier signal and output the second group signal to a second one of the local data registers;
generate a third group signal including one-fourth of the data bits included in the sense amplifier signal and output the third group signal to a third one of the local data registers; and
generate a fourth group signal including one-fourth of the data bits included in the sense amplifier signal and output the fourth group signal to a fourth one of the local data registers.

5. The memory device of claim 4, wherein, when the output mode is the single-bit serial mode,
the first one of the four local data registers is configured to generate a first serial data output signal including all of the data bits included in the first group signal and output the first serial data output signal to a first one of the four output circuits.

6. The memory device of claim 5, wherein the first one of the four output circuits is configured to sequentially output the data bits included in the first serial data output signal.

7. The memory device of claim 4, wherein, when the output mode is the two-bit serial mode,
the first one of the four local data registers is configured to generate a first serial data output signal including one-half of the data bits included in the first group signal and output the first serial data output signal to a first one of the four output circuits; and
the second one of the four local data registers is configured to generate a second serial data output signal including all of the data bits included in the second group signal and output the second serial data output signal to a second one of the four output circuits.

8. The memory device of claim 7, wherein the first and second ones of the output circuits are configured to concurrently and sequentially output the data bits included in the respective ones of the first and second serial data output signals.

9. The memory device of claim 4, wherein, when the output mode is the four-bit serial mode,
the first one of the four local data registers is configured to generate a first serial data output signal including one-fourth of the data bits included in the first group signal and output the first serial data output signal to a first one of the four output circuits;
the second one of the four local data registers is configured to generate a second serial data output signal including one-half of the data bits included in the second group signal and output the second serial data output signal to a second one of the four output circuits;
the third one of the four local data registers is configured to generate a third serial data output signal including all of the data bits included in the third group signal and output the third serial data output signal to a third one of the four output circuits; and
the fourth one of the four local data registers is configured to generate a fourth serial data output signal including all of the data bits included in the fourth group signal and output the fourth serial data output signal to a fourth one of the four output circuits.

10. The memory device of claim 9, wherein the first to fourth ones of the four output circuits are configured to concurrently and sequentially output the data bits included in the respective ones of the first to fourth serial data output signals.

11. The memory device of claim 1, wherein:
the memory array includes a plurality of memory arrays separated from each other and each storing data; and
the sense amplifier includes a plurality of sense amplifiers coupled to respective ones of the plurality of memory arrays and configured to read data bits from the respective ones of the plurality of memory arrays and output a plurality of sense data signals including the data bits read from the respective ones of the plurality of memory arrays.

12. The memory device of claim 11, wherein the data multiplexer is coupled to the plurality of sense amplifiers to receive the plurality of sense data signals, and is configured to combine the plurality of sense data signals to generate the sense amplifier signal.

13. A method for reading data from a memory device including a memory array, a sense amplifier coupled to the memory array, a data multiplexer coupled to the sense amplifier, a plurality of local data registers independent of each other and coupled to the data multiplexer, and a plurality of output circuits respectively independent of each other and coupled to the plurality of local data registers, the method comprising:
reading, by the sense amplifier, a plurality of data bits from the memory array to generate a sense data signal including the plurality of data bits read from the memory array;
generating, by the data multiplexer, a sense amplifier signal from the sense data signal;
selecting, by the data multiplexer, a plurality of groups of data bits from the sense amplifier signal to generate a plurality of group signals;
receiving, by the plurality of local data registers, respective ones of the plurality of group signals generated by the data multiplexer;
generating, by each one of the local data registers, a serial data output signal including at least a subset of the data bits included in a corresponding one of the group signals according to an output mode, and outputting the serial data output signal to a corresponding one of the output circuits; and
sequentially outputting, by each one of the output circuits, the data bits included in the corresponding serial data output signal.

14. The method of claim 13, wherein the memory device includes four of the local data registers and four of the output circuits,
the output mode being one of a single-bit serial mode, a two-bit serial mode, and a four-bit serial mode.

15. The method of claim 14, wherein the selecting, by the data multiplexer, the plurality of groups of data bits from the sense amplifier signal to generate a plurality of group signals, includes:
generating a first group signal including all of the data bits included in the sense amplifier signal and outputting the first group signal to a first one of the local data registers;
generating a second group signal including one-half of the data bits included in the sense amplifier signal and outputting the second group signal to a second one of the local data registers;
generating a third group signal including one-fourth of the data bits included in the sense amplifier signal and outputting the third group signal to a third one of the local data registers; and
generating a fourth group signal including one-fourth of the data bits included in the sense amplifier signal and outputting the fourth group signal to a fourth one of the local data registers.

16. The method of claim 15, wherein, when the output mode is the single-bit serial mode, the method including:
generating, by the first one of the four local data registers, a first serial data output signal including all of the data bits included in the first group signal and outputting the first serial data output signal to a first one of the four output circuits; and
sequentially outputting, by the first one of the four output circuits, the data bits included in the first serial data output signal.

17. The method of claim 15, wherein, when the output mode is the two-bit serial mode, the method including:
generating, by the first one of the four local data registers, a first serial data output signal including one-half of the data bits included in the first group signal and outputting the first serial data output signal to a first one of the four output circuits; and
generating, by the second one of the four local data registers, a second serial data output signal including all of the data bits included in the second group signal and outputting the second serial data output signal to a second one of the four output circuits.

18. The method of claim 17, further including:
concurrently and sequentially outputting, by the first and second ones of the output circuits, the data bits included in the respective ones of the first and second serial data output signals.

19. The method of claim 15, wherein, when the output mode is the four-bit serial mode, the method including:
generating, by the first one of the four local data registers, a first serial data output signal including one-fourth of the data bits included in the first group signal and outputting the first serial data output signal to a first one of the four output circuits;
generating, by the second one of the four local data registers, a second serial data output signal including one-half of the data bits included in the second group signal and outputting the second serial data output signal to a second one of the four output circuits;
generating, by the third one of the four local data registers, a third serial data output signal including all of the data bits included in the third group signal and outputting the third serial data output signal to a third one of the four output circuits; and
generating, by the fourth one of the four local data registers, a fourth serial data output signal including all of the data bits included in the fourth group signal and outputting the fourth serial data output signal to a fourth one of the four output circuits.

20. The method of claim 19, further including:
concurrently and sequentially outputting, by the first to fourth ones of the four output circuits, the data bits included in the respective ones of the first to fourth serial data output signals.
